(19) United States
(12) Patent Application Publication
(10) Pub. No.: US 2025/0239489 A1
(43) Pub. Date: Jul. 24, 2025

(54) VERTICAL WIRING OF A SEMICONDUCTOR COMPONENT

(71) Applicants: Siemens Healthineers AG, Forchheim (DE); FRAUNHOFER-GESELLSCHAFT ZUR FÖRDERUNG DER ANGEWANDTEN FORSCHUNG E.V., München (DE)

(72) Inventors: Michael HOSEMANN, Erlangen (DE); Kay VIEHWEGER, Ortrand (DE); Anna GABIGER-ROSE, Nuernberg (DE)

(73) Assignees: Siemens Healthineers AG, Forchheim (DE); FRAUNHOFER-GESELLSCHAFT ZUR FÖRDERUNG DER ANGEWANDTEN FORSCHUNG E.V., München (DE)

(21) Appl. No.: 19/035,401

(22) Filed: Jan. 23, 2025

(30) Foreign Application Priority Data
Jan. 24, 2024 (DE) 10 2024 200 633.5

(51) Int. Cl. H01L 21/768; H01L 21/66; H01L 23/00; H01L 23/31; H01L 25/16; H10F 30/00

(52) U.S. Cl. CPC H01L 21/76898; H01L 21/76831; H01L 21/76846; H01L 22/32; H01L 23/3171; H01L 24/03; H01L 25/167; H01L 24/05; H01L 2224/0391; H01L 2224/05644; H10F 30/301

(57) ABSTRACT

A semiconductor component includes a semiconductor substrate, a first electrical insulation layer on a front side, a second electrical insulation layer on the first electrical insulation layer, and a contact surface for the semiconductor substrate in or on the second electrical insulation layer. A method for making a recess for a through contact comprises: creating a blind hole-like recess through the semiconductor substrate to the first electrical insulation layer; removing the first electrical insulation layer within the blind hole-like recess; expanding the blind hole-like recess in a direction towards the contact surface by partially removing the second electrical insulation layer; applying a third electrical insulation layer to inner walls of the expanded recess, wherein the first electrical insulation layer is covered up to the expanded recess; and anisotropic etching the second electrical insulation layer towards the contact surface until the contact surface for the semiconductor substrate is revealed.

### CROSS-REFERENCE TO RELATED APPLICATION(S)

The present application claims priority under 35 U.S.C. § 119 to German Patent Application No. 10 2024 200 633.5, filed Jan. 24, 2024, the entire contents of which is incorporated herein by reference.

### FIELD

One or more example embodiments of the present invention relate to a method for making a recess or cutout for a through-contact in a semiconductor component. One or more example embodiments of the present invention also relate to a method for making a through-contact in a semiconductor component. One or more example embodiments of the present invention furthermore relate to a semiconductor component. Moreover, one or more example embodiments of the present invention relate to an x-ray detector module with such a semiconductor component.

### BACKGROUND

An x-ray detector has plurality of layers with different functions. First of all an x-ray detector has a sensor layer with a sensor material. In what is known as a direct converting x-ray detector, x-ray quantas are converted directly in the sensor material into electrical charge pulses, of which the overall charge represents a measure of the energy of the x-ray quantas. Cadmium telluride or cadmium zinc telluride is preferably employed as the sensor material for such a direct converting x-ray detector. The sensor layer forms an active pixel surface for detection of x-ray radiation. While an x-ray is being recorded a continuous pulse train is produced by the detected x-rays in the sensor layer.

The pulses created in this way are counted by a counting unit connected downstream of the sensor layer, preferably an ASIC, in a counting interval that can be set, and measured as to their height. Such a counting unit has a plurality of signal processing channels, which are arranged in a specific pixel matrix, so-called subpixels. Each subpixel is to measure the number of pulses in the pulse train. In this case the height of the charge pulses is compared with a predetermined set of thresholds and the corresponding number of pulses is noted. Assuming that the absorption of an x-ray photon triggers precisely one charge pulse, then the pulse number corresponds to the number of the absorbed x-ray photons. Assuming that the height of the pulse is proportional to the energy of the x-ray photon, the threshold mentioned above can further be equated with an energy threshold.

The circuitry or active circuitry of the counting unit, in particular of the ASICs, are arranged on the upper side of a semiconductor substrate of an x-ray detector module, i.e. on the side of the semiconductor substrate that faces towards an x-ray source, mostly in the so-called CMOS layer (CMOS stands for Complementary Metal Oxide Semiconductor). The active circuitry forms an integrated circuit with the semiconductor substrate.

Connected to the ASICS or to the semiconductor substrate is a carrier substrate, which can have a ceramic or a circuit board material as its material. Through contacts run through the layer of the ASICs and also through the semiconductor substrate, which pass on the count signals created by the ASICs to the carrier substrate mentioned, in which a charge reversal of count signals and a distribution of control signals and energy flows takes place. This carrier substrate is therefore also referred to below as a distributor unit. Combined signals are forwarded from the distributor unit via ribbon cables to an evaluation unit, also referred to as the module backplane.

The active pixel surface of an x-ray detector must be as large as possible in order to be able to detect as much as possible of the x-ray radiation that has passed through the patient. In this case wiring that restricts the surface that is able to be used for detection causes disruptions. At the same time the connecting elements used must be robust as regards mechanical loads and must be stable over the long term, without negatively influencing the electrical capability (by resistances or leakage currents for example). The process for production of the connecting elements must be compatible with the sensors and integrated circuits to be connected. After each production step a check on the parts produced must be able to be made. Test contacts should be able to be connected to the ASICS and sensors in order to be able to test the sensors and ASICS even while they are being manufactured.

### SUMMARY

If so-called through contacts are used as connecting elements, it is important that the structure of the sensor chip or of the semiconductor component carrying the counting unit is not damaged during the formation of the through contacts.

An object of one or more embodiments of the present invention is to develop a manufacturing process for a semiconductor component and such a semiconductor component, in particular an x-ray detector module with such a semiconductor component, which will simplify a testability of such a semiconductor component during manufacturing and let it be more effective.

At least this object is achieved by a method for making a recess for a through contact in a semiconductor component, by a method for making a through contact in a semiconductor component, by a semiconductor component as claimed and by an x-ray detector module as claimed.

In an embodiment of the inventive method for making a recess for a through contact in a semiconductor component, first of all a semiconductor component is provided as an initial product. The semiconductor component already has a multiplicity of basic elements, which are embodied as electronic circuits, for avoidance of short circuits and for a test of the electronic circuits.

These basic elements comprise a semiconductor substrate with a rear side and a front side. Both the said sides in this case are formed by the two flat sides of the semiconductor substrate. Embodied on the front side of the semiconductor substrate is a first electrical insulation layer. A second electrical insulation layer is arranged on the first electrical insulation layer.

The semiconductor component also comprises a contact surface for the semiconductor substrate in or on the second electrical insulation layer and preferably a test contact on the contact surface.

Within the framework of embodiments of the inventive method, first of all a blind hole-like recess is created or embodied through the semiconductor substrate as far as the first electrical insulation layer. Within the blind hole-like recess the first electrical insulation layer is removed. The recess is extended in the vertical direction, i.e. transverse to the contact surface and towards the contact surface, preferably by part removal of the second electrical insulation layer. Furthermore, a third electrical insulation layer is attached to inner walls of the expanded recess, wherein the first electrical insulation layer is covered up towards the expanded recess. Finally an anisotropic vertical etching takes place, i.e. transverse to the layer sequence of the second electrical insulation layer, until the contact surface is revealed towards the semiconductor substrate and the recess for the through contact is thus completely embodied. In the anisotropic etching the second electrical insulation layer and the third electrical insulation layer are completely removed from the contact surface. Advantageously the first electrical insulation layer is protected by the third electrical insulation layer against damage during the anisotropic etching. This is because it is often possible that, without any suitable protection during the anisotropic etching, the first electrical insulation layer will be damaged, which can contribute to a defect or to worsened functional characteristics of the semiconductor component. In particular lateral etchings into the first electrical insulation layer should be avoided during the anisotropic etching step. This is because such etchings can represent starting points for mechanical tears in the semiconductor component. The protection of the first electrical insulation layer is especially effective and sensible when the material of the first electrical insulation layer reacts especially sensitively to the anisotropic etching step, whereas the material of the second and third electrical insulation layer, which preferably differs from the material of the first electrical insulation layer, reacts relatively robustly to the anisotropic etching, in particular as regards the lateral underetching of the respective layer. It should be pointed out that the recess for a through contact is not restricted to use on semiconductor substrates of x-ray detector modules, but can also be used for other sensor components, such as for example sensor components of optical image recording units working on a pixel basis.

In an embodiment of the inventive method for making a through contact in a semiconductor component, an embodiment of the inventive method for making a recess for a through contact in a semiconductor component is carried out. Furthermore, a barrier layer is applied to a surface of the third electrical insulation layer pointing away from the first electrical insulation layer and to the contact surface in the recess. Preferably the recess is completely clad with the barrier layer. The barrier layer prevents conductor material, which is to be attached during the subsequent step, diffusing into layers and areas lying below it.

Subsequently a conductor track is applied to the semiconductor substrate and in the recess on the barrier layer. The conductor track forms an electrical connection between the rear side of the semiconductor substrate and the contact surface of the semiconductor component.

Subsequently a first rear-side passivization layer is applied to the conductor track. The passivization layer protects the conductor track against corrosion.

Attached to the conductor track is a contact element, which forms an electrical contact between the semiconductor component and a neighboring electronic component, preferably a sensor unit of an x-ray detector module. The contact element preferably has gold as its material, which is electrically conductive and very resistant to corrosion. The method for making a through contact in a semiconductor component shares the advantages of the method for making a recess for a through contact in a semiconductor component.

An embodiment of the inventive semiconductor component has a semiconductor substrate with a rear side and a front side. As already explained, the two said sides are formed in this case by the two flat sides of the semiconductor substrate. The semiconductor component has a first electrical insulation layer on the semiconductor substrate and a second electrical insulation layer on the first electrical insulation layer. Furthermore the semiconductor component has a contact surface for the semiconductor substrate on or in the second electrical insulation layer. An embodiment of the inventive semiconductor component has a recess for a through contact between the semiconductor substrate and the contact surface. The recess extends through the contact surface. Furthermore, a third electrical insulation layer is embodied on inner walls of the recess, wherein the first electrical insulation layer is covered up to the recess by the third electrical insulation layer.

An embodiment of the inventive x-ray detector module has a sensor unit and an embodiment of an inventive semiconductor component. The semiconductor substrate of the semiconductor component has counting electronics, which are electrically connected to the semiconductor component. An embodiment of the inventive x-ray detector module also has a distribution unit, which is electrically connected to an embodiment of the inventive semiconductor component. The x-ray detector module moreover comprises an evaluation unit, which is electrically connected to the distribution unit, preferably by one or more ribbon cables. The x-ray detector module shares the advantages of embodiments of the inventive semiconductor component.

Embodiments of the present invention also comprise a control facility (also referred to as a control device) for controlling the steps for carrying out embodiments of the inventive method for making a recess for a through contact in a semiconductor component and embodiments of the inventive method for making a through contact in a semiconductor component. The control facility can in particular activate a semiconductor production facility (also referred to as a semiconductor production apparatus or device) in order to carry out the steps of embodiments of the inventive method for making a recess for a through contact in a semiconductor component or of embodiments of the inventive method for making a through contact in a semiconductor component.

A large part of the above-mentioned control facility for controlling the steps of embodiments of the inventive method for making a recess for a through contact in a semiconductor component and of embodiments of the inventive method for making a through contact in a semiconductor component can be realized entirely or in part in the form of software modules in a processor of a corresponding computer system, for example by a control facility of a facility for making a semiconductor component or by a semiconductor production facility. A largely software-based realization has the advantage that computer systems used previously for production control of semiconductor components can also be upgraded in a simple way by a software update in order to work in the inventive way. To this extent the object is achieved by a corresponding computer program product with a computer program, which is able to be loaded directly into a computer system, with program sections for carrying out control processes in order to implement the steps of embodiments of the inventive method for making a recess for a through contact in a semiconductor component or of the method for making a through contact in a semiconductor component. Such a computer program product, as well as the computer program, can where necessary comprise additional elements such as for example documentation and/or additional components, also hardware components, such as for example hardware keys (dongles etc.) for use of the software.

For transport to the computer system or to the control facility and/or for storage at or in the computer system or the control facility a computer-readable medium, for example a memory stick, a hard disk or any other transportable or permanently installed data carrier can be used, on which the program sections of the computer program able to be read in and executed by a computer system are stored. The computer system can have one or more interoperating microprocessors or the like for this for example.

The dependent claims, as well as the description given below each contain especially advantageous embodiments and developments of the present invention. In this case the claims of one claim category can in particular also be further developed in a similar way to the dependent claims of another claim category. Moreover, within the framework of the present invention, the various features of different exemplary embodiments and claims can also be combined to form new exemplary embodiments.

In a preferred variant of an embodiment of the inventive method for making a recess for a through contact in a semiconductor component the first electrical insulation layer comprises silicon nitride and the second and the third electrical insulation layer comprise silicon dioxide. Silicon nitride can for example be employed as masking and stop material in the structuring of the semiconductor substrate.

Preferably the conductor track features one of the following materials:
copper,
aluminum,
tungsten.

Copper, with 58 MS/m (MS=Mega-Siemens), has the best conductivity of the three materials listed. Tungsten is especially capable of resistance. Aluminum is comparatively low-cost and does not tend to diffuse into the substrate material. Tungsten can be used as contact material between aluminum conductor tracks and lines made of other material.

Especially preferably the first rear-side passivization layer features one of the following materials:
nickel,
silicon dioxide,
polyimide.

Nickel is an electrical conductor. Silicon dioxide and lead oxide are electrical insulators. Polyimides are chemically resistant and heat resistant. Polyimides are used in electrical engineering on account of their heat resistance, lower gas emission, radiation resistance and their insulation properties.

In one embodiment of the inventive method for making a through contact in a semiconductor component the rear side of the semiconductor substrate is structured and is provided with a second rear-side passivization layer on the third electrical insulation layer and on the conductor track. Advantageously areas of the rear side of the semiconductor substrate not used for contacting are insulated and protected against corrosion.

Preferably the second rear-side passivization layer features one of the following materials:
polyimide,
silicon nitride,
silicon dioxide.

The said materials are electrical insulators and relatively durable and protect the part of the rear side of the semiconductor substrate not used for contacting against corrosion and leakage currents.

The semiconductor component can have a test contact in contact, in particular in direct physical contact, with the contact surface. The test contact can advantageously be electrically contacted for test purposes by a test facility. Advantageously the semiconductor component and/or elements thereof can be tested via the test contact with respect to their functionality.

The test contact features an electrically conductive material. In particular the test contact can feature copper, nickel, palladium or gold or a combination thereof in layers and/or as a metal alloy. It can however also feature another electrically conductive material. In particular the test contact can feature a different material or a different material combination than the contact surface. For example, the contact surface features copper and aluminum. For example the test contact features copper and gold. Advantageously the test contact has a high electrical conductivity and good contactability. In particular the test contact can be embodied as a massive structure. The test contact can be embodied in this case without intermediate insulating layers.

The test contact can essentially be arranged overlapping with the planar extent of the contact surface. The planar extent of the test contact can essentially match the planar extent of the contact surface. It can however also be smaller or larger. In particular the planar extent of the test contact can stretch at least for the greater part over the planar extent of the contact surface. Advantageously a combination of the TSV contact surface and test contact lying above it can limit the amount of space needed without having to do without the possibility of test contacting. In this way it can be prevented that chip surface is not able to be used for other functions, such as for example active circuitry. The form of the contact surface and of the test contact can be chosen to be similar or different in this case.

The test contact can have an overall material thickness, i.e. an extent of the test contact at right angles to the front side of the semiconductor, which is greater than the thickness of the contact surface material. In this the contact surface can be built up in layers comprising metal layers and layers comprising an insulating material. If the contact surface has a number of metal layers, then the test contact can in particular be embodied thicker than each of the metal layers of the contact surface. In particular the overall material thickness of the test contact can be greater than the overall thickness of the material of the contact surface, i.e. comprising all material layers. The test contact can be embodied around 1.5 to 3 times thicker that the overall material thickness of the contact surface. For example the test contact is embodied twice as thick. Advantageously the material of the test contact strengthens the structure or the area over the recess for the through contact and makes this or these mechanically more robust. In this way a through contact and in particular also a plurality of through contacts can be provided in a semiconductor component, wherein at the same time a semiconductor component that is mechanically stable and less prone to breakages during and/or after the formation of the recesses is guaranteed. In particular the test contact can be embodied in this case as a massive element from one or from a combination of electrically conducting materials, so that an especially advantageous robustness is guaranteed.

Furthermore, a passivization layer can be applied to the front side of the semiconductor component, for example made of polyimide or lead oxide, which leaves the test contact available.

### BRIEF DESCRIPTION OF THE DRAWINGS

The present invention will be explained once more in greater detail below with reference to the enclosed figures with the aid of exemplary embodiments. In the figures:

FIG. 1 shows a schematic diagram of an x-ray detector module,

FIG. 2 shows a schematic diagram of a semiconductor component, which is used as a substrate for a counting unit of an x-ray detector module,

FIG. 3 shows a schematic diagram of a step for etching a blind hole-like recess in a semiconductor component within the framework of the method for making a recess for a through contact in a semiconductor component in accordance with an exemplary embodiment of the present invention,

FIG. 4 shows a schematic diagram of a step for removal of a first electrical insulation layer in the region of the recess within the framework of the method for making a recess for a through contact in a semiconductor component in accordance with an exemplary embodiment of the present invention,

FIG. 5 shows a schematic diagram of a step for applying a third electrical insulation layer within the framework of the method for making a recess for a through contact in a semiconductor component in accordance with an exemplary embodiment of the present invention,

FIG. 6 shows a schematic diagram of a step for anisotropic vertical etching of the second electrical insulation layer for revealing the test contact within the framework of the method for making a recess for a through contact in a semiconductor component in accordance with an exemplary embodiment of the present invention,

FIG. 7 shows a schematic diagram of a step for applying a barrier layer to the surface of the third electrical insulation layer and to the test contact in the recess within the framework of the method for making a through contact in a semiconductor component in accordance with an exemplary embodiment of the present invention,

FIG. 8 shows a schematic diagram of the step for applying a conductor track to a semiconductor substrate and in the recess on the barrier layer within the framework of the method for making a through contact in a semiconductor component in accordance with an exemplary embodiment of the present invention,

FIG. 9 shows a schematic diagram of the step for applying a first rear-side passivization layer to the conductor track within the framework of the method for making through contact in a semiconductor component in accordance with an exemplary embodiment of the present invention,

FIG. 10 shows a schematic diagram of the step for structuring the rear side of the semiconductor substrate within the framework of the method for making a through contact in a semiconductor component in accordance with an exemplary embodiment of the present invention,

FIG. 11 shows a schematic diagram for application of contact elements to the rear side of the semiconductor substrate within the framework of the method for making a through contact in a semiconductor component in accordance with an exemplary embodiment of the present invention,

FIG. 12 shows a flow diagram, which illustrates a method for making a through contact in a semiconductor component in accordance with an exemplary embodiment of the present invention.

### DETAILED DESCRIPTION

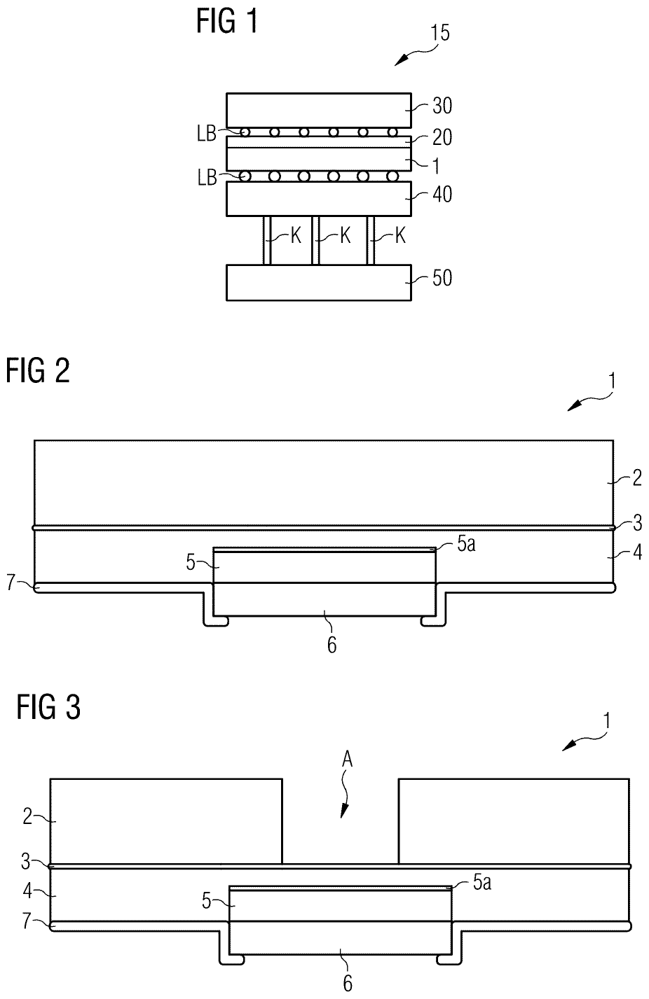

Illustrated in FIG. 1 is a schematic diagram of a direct-converting x-ray detector module 15. Such an x-ray detector module 15 has a sensor unit 30 with a plurality of sensors, which have cadmium telluride as their sensor material for example. The sensor unit 30 is connected via so-called solder balls LB to a semiconductor component 1, which comprises a counting unit 20, which is embodied on the side of the semiconductor component 1 (also referred to as the rear side) facing towards the sensor unit 30, and a plurality of electronic circuits, known as ASICs (ASIC is an acronym für application-specific integrated circuit). The ASICs (not shown in FIG. 1) are electrically connected via through contacts to the underside of the semiconductor component 1.

The x-ray detector module 15 also has a distribution unit 40, which comprises a ceramic material and has lines for power supply to the ASICs in the semiconductor component 1 and for signal distribution. The distribution unit 40 is electrically connected to the semiconductor component 1 via solder balls LB.

An evaluation unit 50, which comprises a modular backplane spatially separate from the above-mentioned units 1, 30, 40, is also part of the x-ray detector module 15. The evaluation unit 50 is electrically connected via ribbon cables K to the distribution unit 40, delivers via the ribbon cables K electrical energy and control data and signal data generated by the sensor unit 30 and the counting unit 20.

Shown in FIG. 2 is a schematic diagram of an output stage of a semiconductor component 1, which can be used for example in an x-ray detector module 15 as carrier of a counting unit 20 of an x-ray detector module 15, which is shown in FIG. 1. The semiconductor component 1 has a semiconductor substrate 2 with a front side and a rear side. The upper side of the semiconductor substrate 2 shown in FIG. 2 should be considered as the rear side and the underside as the front side. Connected to the semiconductor substrate 2 is a first narrow electrical insulation layer 3 on the front side of the semiconductor substrate 2. The first electrical insulation layer 3 comprises silicon nitride for example. Connected to the first electrical insulation layer 3 is a second wide electrical insulation layer 4. The second electrical insulation layer 4 comprises silicon dioxide as its insulation material for example. Integrated into the second electrical insulation layer 4 is a contact surface 5 in the form of a so-called landing pad. The contact surface 5 or the landing pad can also be built up in layers comprising a number of metal layers and layers lying between them comprising insulating material. The landing pad offers an electrical connection to electronic circuits located on the rear side of the semiconductor substrate 2 (not shown). However for this a through contact must be created from the rear side of the semiconductor substrate 2 to the contact surface 5, which is comprehensively illustrated in FIG. 3 to FIG. 11. On the rear side of the contact surface 5 or of the landing pad, i.e. on the side of the contact surface 5 facing towards the second electrical insulation layer 4 is located an electrically conductive barrier layer 5a, which can be made from titanium, titanium nitride or tungsten for example. Such a barrier layer 5a can be employed for example as an etch stop layer and protection layer in the subsequent steps for embodiment of a through contact, in order in particular to protect the metal of the contact surface 5 or of the landing pad, for example copper or aluminum. The landing pad or the contact surface 5 is connected to a test contact 6. For test purposes this can be electrically contacted by a test facility (not shown). The test contact 6 is arranged overlapping with the planar extent of the contact surface 5 or of the landing pad. In particular the test contact 6 is embodied directly above the contact surface 5 or the landing pad. In particular, as shown here in FIG. 2, the planar extent of the test contact 6 can essentially match the planar extent of the contact surface 5 or of the landing pad. It can however be smaller or larger. The test contact 6 features an electrically conductive material, for example copper, nickel, palladium or gold, or combinations as a metal alloy or in layers. The test contact 6 comprises for example metal compounds made of copper and nickel or palladium or gold. In particular the test contact 6 can be embodied as a massive structure. Via the test contact 6 the electronic circuits (not shown) located on the rear side of the semiconductor substrate 2 can be tested. Applied to the front side of the semiconductor component 1 is a passivization layer 7, which is embodied for example from polyimide or lead oxide and leaves the test contact 6 free, so that an electrical contacting of the test contact by a test facility continues to be possible.

The material thickness of the test contact 6, i.e. an extent of the test contact 6 at right angles to the front side of the semiconductor can, in advantageous variants, in this case in particular also be larger than the material thickness of the contact surface 5. If the contact surface 5 has a number of layers of metal, then the test contact 6 is in particular embodied thicker than each of the metal layers of the contact surface 5. In particular however the overall material thickness of the test contact 6 can be greater than the overall material thickness, i.e. comprising all layers, of the contact surface 5. Through the material of the test contact 6 the structure or the area over the recess A for the through contact is strengthened and makes this or these mechanically more robust.

Illustrated in FIG. 3 is a schematic diagram of a step for etching of a blind hole-like recess A in a semiconductor component 1 within the framework of the method for making a recess A″ for a through contact in a semiconductor component 1 in accordance with an exemplary embodiment of the present invention. The blind hole-like recess A is positioned at a point in the semiconductor substrate 2 of the semiconductor component 1 at which a through contact as an electrical connection between the electronic circuits located on the rear side of the semiconductor substrate 2 and the landing pad or the contact surface 5 is to be embodied.

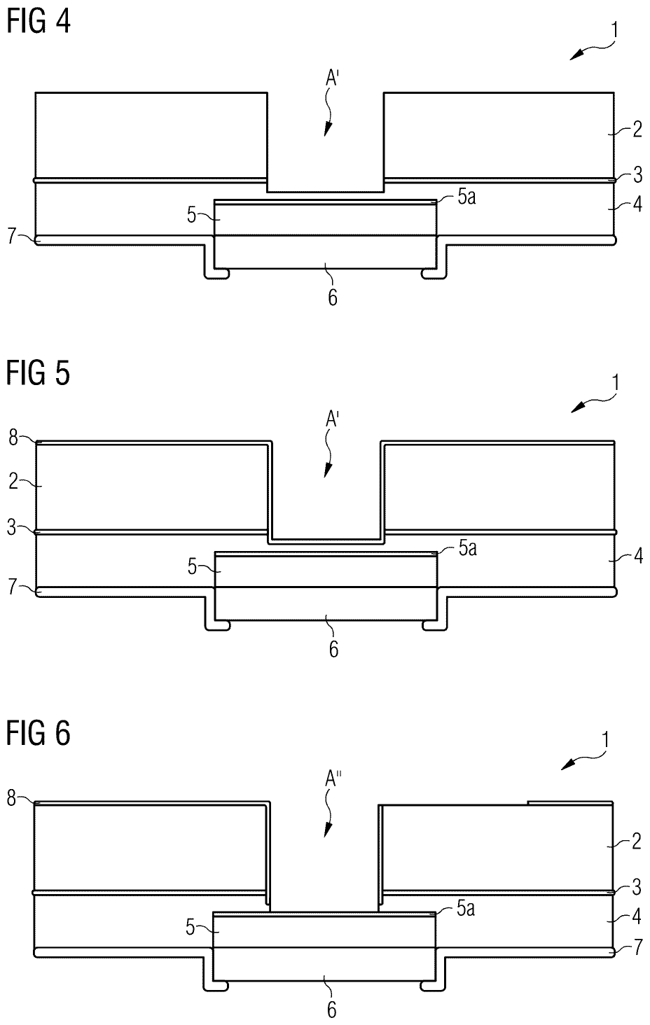

Illustrated in FIG. 4 is a schematic diagram of a step for removing the first electrical insulation layer 3 in the area of the recess A within the framework of the method for making a recess A″ for a through contact in a semiconductor component 1 in accordance with an exemplary embodiment of the present invention. In the step shown in FIG. 4, figuratively speaking the floor of the blind hole created in the step shown in FIG. 3 or of the blind hole-like recess A, which is formed by the first electrical insulation layer 3, is removed by etching. Furthermore, the second electrical insulation layer 4 is also etched somewhat, but not completely, i.e. in particular not through to the barrier layer 5a, which separates the second electrical insulation layer 4 from the landing pad or the contact surface 5.

Illustrated In FIG. 5 is a schematic diagram of a step for applying a third electrical insulation layer 8 within the framework of the method for making a recess A″ for a through contact in a semiconductor component 1 in accordance with an exemplary embodiment of the present invention. The third electrical insulation layer 8 is inserted both into the expanded blind hole of the deepened recess A′ and also embodied on the rear side of the semiconductor substrate 2. The third electrical insulation layer 8 comprises silicon dioxide or plastics as its material and in particular covers the first electrical insulation layer 3 up to the deepened recess A′, so that in the next etching step, which is illustrated in FIG. 6, the first electrical insulation layer 3 is not etched in the horizontal direction, which could lead to tears in the semiconductor component 1 and to short circuits or malfunctions of electronic circuits located in the semiconductor component 1.

Illustrated in FIG. 6 is a schematic diagram of a step for anisotropic vertical etching of the second electrical insulation layer 4 to reveal the barrier layer 5a located on the contact surface 5 within the framework of the method for making a recess A″ in a semiconductor component 1 in accordance with an exemplary embodiment of the present invention. Anisotropic etching can for example be realized by exploiting an orientation of a crystal structure of a material. In any event a directed etching in the vertical direction takes place, i.e. in the direction of the sequence of layers towards the barrier layer 5a. By the anisotropic etching towards the barrier layer 5a the recess A″, which is needed for the formation of a through contact, is completely embodied in the semiconductor component 1.

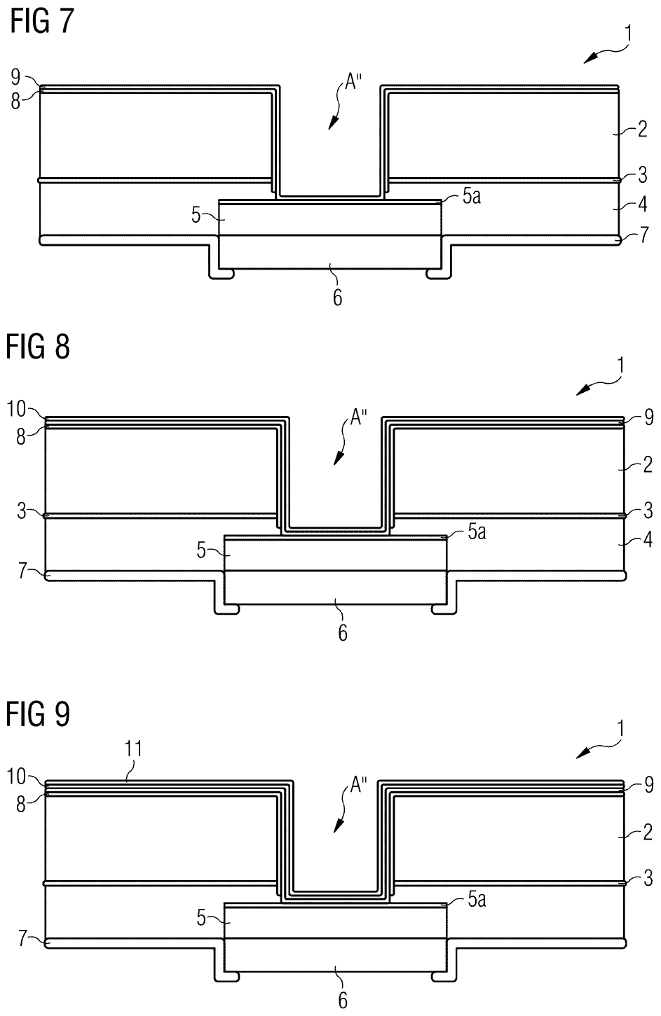

Illustrated in FIG. 7 is a schematic diagram of a step for applying a barrier layer 9 to the surface of the third electrical insulation layer 8 and to the barrier layer 5a in the recess within the framework of the method for making a through contact in a semiconductor component in accordance with an exemplary embodiment of the present invention. The barrier layer 9 comprises titanium or tungsten as its material for example. The barrier layer 9 prevents conductor material subsequently applied penetrating into the third electrical insulation layer 8.

Illustrated in FIG. 8 is a schematic diagram of the step for applying a conductor track 10 to the semiconductor substrate 2 and in the recess A″ on the barrier layer 9 within the framework of the method for making a through contact in a semiconductor component 1 in accordance with an exemplary embodiment of the present invention. The conductor track 10 can for example comprise materials that conduct electricity well, such as copper, aluminum or tungsten, and be embodied as one or as two layers.

Illustrated in FIG. 9 is a schematic diagram of the step for applying a first rear-side passivization layer 11 to the conductor track 10 within the framework of the method for making a through contact in a semiconductor component 1 in accordance with an exemplary embodiment of the present invention. The passivization layer 11 protects the material of the conductor track 10 against corrosion.

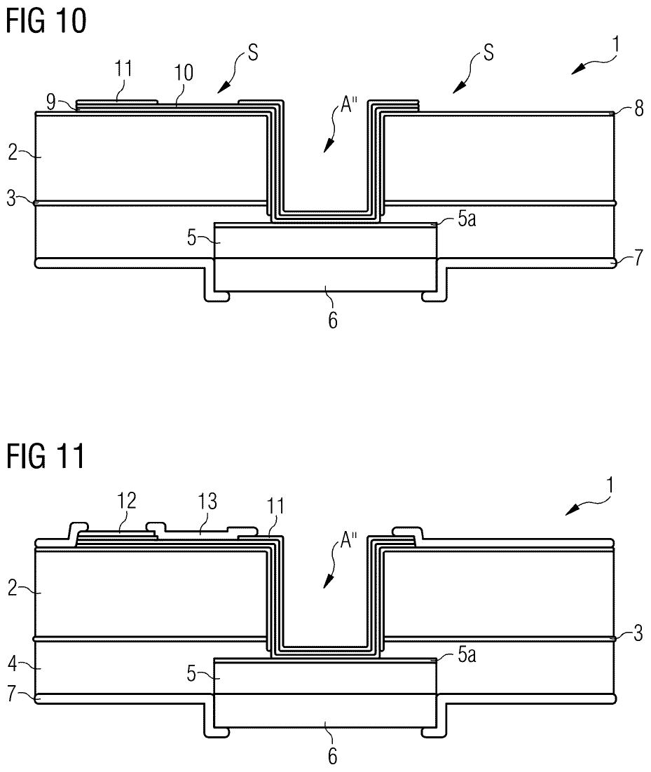

Illustrated in FIG. 10 is a schematic diagram of the step for structuring the rear side of the semiconductor substrate 2 within the framework of the method for making a through contact in a semiconductor component in accordance with an exemplary embodiment of the present invention. The structuring of the rear side of the semiconductor substrate 2 (in FIG. 10 the rear side is the upper side as in the other FIGS. 2 to 9 and 11) in particular comprises the part removal of the rear-side passivization layer 11 and also the part removal of the conductor track 10 as well as the barrier layer 9.

Illustrated in FIG. 11 is a schematic diagram of the step for applying a contact element 12 to the rear side of the semiconductor substrate 2 within the framework of the method for making a through contact in a semiconductor component 1 in accordance with an exemplary embodiment of the present invention. The contact element 12 can be designed as a so called solder pad and feature gold as its material. Furthermore, a second rear-side passivization layer 13 is also applied to the rear side of the semiconductor substrate 2, in order to protect the conductor track 10 against corrosion. The contact element 12 can be electrically connected by a so-called solder ball LB (see FIG. 1) to the sensors 1a (see FIG. 1).

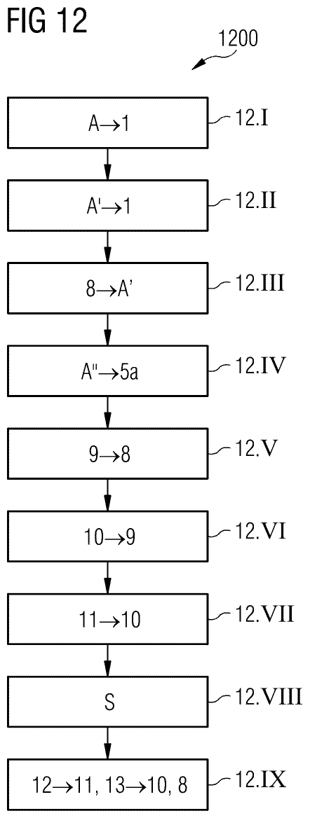

Shown in FIG. 12 is a flow diagram 1200, which illustrates a method for making a through contact in a semiconductor component 1 in accordance with an exemplary embodiment of the present invention.

In step 12.I, first of all the etching step already illustrated in FIG. 3 is carried out, in which a blind hole-like recess A is embodied through the semiconductor substrate 2 of the semiconductor component 1 as far as the first electrical insulation layer 3.

In step 12. II the first electrical insulation layer 3 is removed within the blind hole-like recess A and the recess A is expanded in the vertical direction in the direction of a barrier layer 5a of a contact surface 5 by etching the second electrical insulation layer 4, without reaching the barrier layer 5a, wherein a deepened recess A′ arises, as already illustrated graphically in FIG. 4.

In step 12. III a third electrical insulation layer 8 is applied to inner walls of the expanded or deepened recess A′, wherein the first electrical insulation layer 3 is covered up to the expanded recess A′. The step 12. III has already been shown in the diagram in FIG. 5.

In step 12. IV the second electrical insulation layer 4 is anisotropically etched vertically in the area of the deepened recess A′, until the barrier layer 5a of the landing pad 5 or the contact surface 5 above the test contact 6 is revealed and the recess A″ for the through contact is completely embodied, as is already shown in FIG. 6.

In step 12. V a barrier layer 9 is applied to the surface of the third electrical insulation layer 8 and to the test contact 6 in the recess A″. This step is already shown in FIG. 7.

In step 12.VI a conductor track 10 is applied to the semiconductor substrate 2 and in the recess A″ on the barrier layer. This step is illustrated graphically in FIG. 8.

In step 12.VII a first rear-side passivization layer 11 is applied to the conductor track 10. This step is already shown in the diagram in FIG. 9.

In step 12. VIII a structuring S is undertaken on the rear side of the semiconductor substrate 2. This structuring S can be seen in FIG. 10 on the rear side of the semiconductor substrate 2 (shown there as the upper side).

In step 12. IX contact elements 12 are applied to the rear side of the semiconductor substrate 2 and a rear-side passivation layer 13 is applied to the rear side of the semiconductor substrate 2.

In conclusion it is pointed out once again that the method described in detail above, as well as the apparatus shown, merely represent exemplary embodiments, and that the basic principle can be modified by the person skilled in the art in a very wide variety of ways, without departing from the scope of the present invention, as specified by the claims. It is also pointed out for the sake of completeness that the use of the indefinite article “a” or “an” does not exclude the features concerned from also being able to be present a number of times. Likewise the term “unit” does not exclude this from consisting of a number of components that can, if necessary, also be spatially distributed.

Independent of the grammatical term usage, individuals with male, female or other gender identities are included within the term.

It will be understood that, although the terms first, second, etc. may be used herein to describe various elements, components, regions, layers, and/or sections, these elements, components, regions, layers, and/or sections, should not be limited by these terms. These terms are only used to distinguish one element from another. For example, a first element could be termed a second element, and, similarly, a second element could be termed a first element, without departing from the scope of example embodiments. As used herein, the term “and/or,” includes any and all combinations of one or more of the associated listed items. The phrase “at least one of” has the same meaning as “and/or”.

Spatially relative terms, such as “beneath,” “below,” “lower,” “under,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below,” “beneath,” or “under,” other elements or features would then be oriented “above” the other elements or features. Thus, the example terms “below” and “under” may encompass both an orientation of above and below. The device may be otherwise oriented (rotated 90 degrees or at other orientations) and the spatially relative descriptors used herein interpreted accordingly. In addition, when an element is referred to as being “between” two elements, the element may be the only element between the two elements, or one or more other intervening elements may be present.

Spatial and functional relationships between elements (for example, between modules) are described using various terms, including “on,” “connected,” “engaged,” “interfaced,” and “coupled.” Unless explicitly described as being “direct,” when a relationship between first and second elements is described in the disclosure, that relationship encompasses a direct relationship where no other intervening elements are present between the first and second elements, and also an indirect relationship where one or more intervening elements are present (either spatially or functionally) between the first and second elements. In contrast, when an element is referred to as being “directly” on, connected, engaged, interfaced, or coupled to another element, there are no intervening elements present. Other words used to describe the relationship between elements should be interpreted in a like fashion (e.g., “between,” versus “directly between,” “adjacent,” versus “directly adjacent,” etc.).

The terminology used herein is for the purpose of describing particular embodiments only and is not intended to be limiting of example embodiments. As used herein, the singular forms “a,” “an,” and “the,” are intended to include the plural forms as well, unless the context clearly indicates otherwise. As used herein, the terms “and/or” and “at least one of” include any and all combinations of one or more of the associated listed items. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Expressions such as “at least one of,” when preceding a list of elements, modify the entire list of elements and do not modify the individual elements of the list. Also, the term “example” is intended to refer to an example or illustration.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, e.g., those defined in commonly used dictionaries, should be interpreted as having a meaning that is consistent with their meaning in the context of the relevant art and will not be interpreted in an idealized or overly formal sense unless expressly so defined herein.

It is noted that some example embodiments may be described with reference to acts and symbolic representations of operations (e.g., in the form of flow charts, flow diagrams, data flow diagrams, structure diagrams, block diagrams, etc.) that may be implemented in conjunction with units and/or devices discussed above. Although discussed in a particularly manner, a function or operation specified in a specific block may be performed differently from the flow specified in a flowchart, flow diagram, etc. For example, functions or operations illustrated as being performed serially in two consecutive blocks may actually be performed simultaneously, or in some cases be performed in reverse order. Although the flowcharts describe the operations as sequential processes, many of the operations may be performed in parallel, concurrently or simultaneously. In addition, the order of operations may be re-arranged. The processes may be terminated when their operations are completed, but may also have additional steps not included in the figure. The processes may correspond to methods, functions, procedures, subroutines, subprograms, etc.

Specific structural and functional details disclosed herein are merely representative for purposes of describing example embodiments. The present invention may, however, be embodied in many alternate forms and should not be construed as limited to only the embodiments set forth herein.

In addition, or alternative, to that discussed above, units and/or devices according to one or more example embodiments may be implemented using hardware, software, and/or a combination thereof. For example, hardware devices may be implemented using processing circuitry such as, but not limited to, a processor, Central Processing Unit (CPU), a controller, an arithmetic logic unit (ALU), a digital signal processor, a microcomputer, a field programmable gate array (FPGA), a System-on-Chip (SoC), a programmable logic unit, a microprocessor, or any other device capable of responding to and executing instructions in a defined manner. Portions of the example embodiments and corresponding detailed description may be presented in terms of software, or algorithms and symbolic representations of operation on data bits within a computer memory. These descriptions and representations are the ones by which those of ordinary skill in the art effectively convey the substance of their work to others of ordinary skill in the art. An algorithm, as the term is used here, and as it is used generally, is conceived to be a self-consistent sequence of steps leading to a desired result. The steps are those requiring physical manipulations of physical quantities. Usually, though not necessarily, these quantities take the form of optical, electrical, or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind that all of these and similar terms are to be associated with the appropriate physical quantities and are merely convenient labels applied to these quantities. Unless specifically stated otherwise, or as is apparent from the discussion, terms such as “processing” or “computing” or “calculating” or “determining” of “displaying” or the like, refer to the action and processes of a computer system, or similar electronic computing device/hardware, that manipulates and transforms data represented as physical, electronic quantities within the computer system's registers and memories into other data similarly represented as physical quantities within the computer system memories or registers or other such information storage, transmission or display devices.

In this application, including the definitions below, the term ‘module’ or the term ‘controller’ may be replaced with the term ‘circuit.’ The term ‘module’ may refer to, be part of, or include processor hardware (shared, dedicated, or group) that executes code and memory hardware (shared, dedicated, or group) that stores code executed by the processor hardware.

The module may include one or more interface circuits. In some examples, the interface circuits may include wired or wireless interfaces that are connected to a local area network (LAN), the Internet, a wide area network (WAN), or combinations thereof. The functionality of any given module of the present disclosure may be distributed among multiple modules that are connected via interface circuits. For example, multiple modules may allow load balancing. In a further example, a server (also known as remote, or cloud) module may accomplish some functionality on behalf of a client module.

Software may include a computer program, program code, instructions, or some combination thereof, for independently or collectively instructing or configuring a hardware device to operate as desired. The computer program and/or program code may include program or computer-readable instructions, software components, software modules, data files, data structures, and/or the like, capable of being implemented by one or more hardware devices, such as one or more of the hardware devices mentioned above. Examples of program code include both machine code produced by a compiler and higher level program code that is executed using an interpreter.

For example, when a hardware device is a computer processing device (e.g., a processor, Central Processing Unit (CPU), a controller, an arithmetic logic unit (ALU), a digital signal processor, a microcomputer, a microprocessor, etc.), the computer processing device may be configured to carry out program code by performing arithmetical, logical, and input/output operations, according to the program code. Once the program code is loaded into a computer processing device, the computer processing device may be programmed to perform the program code, thereby transforming the computer processing device into a special purpose computer processing device. In a more specific example, when the program code is loaded into a processor, the processor becomes programmed to perform the program code and operations corresponding thereto, thereby transforming the processor into a special purpose processor.

Software and/or data may be embodied permanently or temporarily in any type of machine, component, physical or virtual equipment, or computer storage medium or device, capable of providing instructions or data to, or being interpreted by, a hardware device. The software also may be distributed over network coupled computer systems so that the software is stored and executed in a distributed fashion. In particular, for example, software and data may be stored by one or more computer readable recording mediums, including the tangible or non-transitory computer-readable storage media discussed herein.

Even further, any of the disclosed methods may be embodied in the form of a program or software. The program or software may be stored on a non-transitory computer readable medium and is adapted to perform any one of the aforementioned methods when run on a computer device (a device including a processor). Thus, the non-transitory, tangible computer readable medium, is adapted to store information and is adapted to interact with a data processing facility or computer device to execute the program of any of the above mentioned embodiments and/or to perform the method of any of the above mentioned embodiments.

Example embodiments may be described with reference to acts and symbolic representations of operations (e.g., in the form of flow charts, flow diagrams, data flow diagrams, structure diagrams, block diagrams, etc.) that may be implemented in conjunction with units and/or devices discussed in more detail below. Although discussed in a particularly manner, a function or operation specified in a specific block may be performed differently from the flow specified in a flowchart, flow diagram, etc. For example, functions or operations illustrated as being performed serially in two consecutive blocks may actually be performed simultaneously, or in some cases be performed in reverse order.

According to one or more example embodiments, computer processing devices may be described as including various functional units that perform various operations and/or functions to increase the clarity of the description. However, computer processing devices are not intended to be limited to these functional units. For example, in one or more example embodiments, the various operations and/or functions of the functional units may be performed by other ones of the functional units. Further, the computer processing devices may perform the operations and/or functions of the various functional units without sub-dividing the operations and/or functions of the computer processing units into these various functional units.

Units and/or devices according to one or more example embodiments may also include one or more storage devices. The one or more storage devices may be tangible or non-transitory computer-readable storage media, such as random access memory (RAM), read only memory (ROM), a permanent mass storage device (such as a disk drive), solid state (e.g., NAND flash) device, and/or any other like data storage mechanism capable of storing and recording data. The one or more storage devices may be configured to store computer programs, program code, instructions, or some combination thereof, for one or more operating systems and/or for implementing the example embodiments described herein. The computer programs, program code, instructions, or some combination thereof, may also be loaded from a separate computer readable storage medium into the one or more storage devices and/or one or more computer processing devices using a drive mechanism. Such separate computer readable storage medium may include a Universal Serial Bus (USB) flash drive, a memory stick, a Blu-ray/DVD/CD-ROM drive, a memory card, and/or other like computer readable storage media. The computer programs, program code, instructions, or some combination thereof, may be loaded into the one or more storage devices and/or the one or more computer processing devices from a remote data storage device via a network interface, rather than via a local computer readable storage medium. Additionally, the computer programs, program code, instructions, or some combination thereof, may be loaded into the one or more storage devices and/or the one or more processors from a remote computing system that is configured to transfer and/or distribute the computer programs, program code, instructions, or some combination thereof, over a network. The remote computing system may transfer and/or distribute the computer programs, program code, instructions, or some combination thereof, via a wired interface, an air interface, and/or any other like medium.

The one or more hardware devices, the one or more storage devices, and/or the computer programs, program code, instructions, or some combination thereof, may be specially designed and constructed for the purposes of the example embodiments, or they may be known devices that are altered and/or modified for the purposes of example embodiments.

A hardware device, such as a computer processing device, may run an operating system (OS) and one or more software applications that run on the OS. The computer processing device also may access, store, manipulate, process, and create data in response to execution of the software. For simplicity, one or more example embodiments may be exemplified as a computer processing device or processor; however, one skilled in the art will appreciate that a hardware device may include multiple processing elements or processors and multiple types of processing elements or processors. For example, a hardware device may include multiple processors or a processor and a controller. In addition, other processing configurations are possible, such as parallel processors.

The computer programs include processor-executable instructions that are stored on at least one non-transitory computer-readable medium (memory). The computer programs may also include or rely on stored data. The computer programs may encompass a basic input/output system (BIOS) that interacts with hardware of the special purpose computer, device drivers that interact with particular devices of the special purpose computer, one or more operating systems, user applications, background services, background applications, etc. As such, the one or more processors may be configured to execute the processor executable instructions.

The computer programs may include: (i) descriptive text to be parsed, such as HTML (hypertext markup language) or XML (extensible markup language), (ii) assembly code, (iii) object code generated from source code by a compiler, (iv) source code for execution by an interpreter, (v) source code for compilation and execution by a just-in-time compiler, etc. As examples only, source code may be written using syntax from languages including C, C++, C#, Objective-C, Haskell, Go, SQL, R, Lisp, Java®, Fortran, Perl, Pascal, Curl, OCaml, Javascript®, HTML5, Ada, ASP (active server pages), PHP, Scala, Eiffel, Smalltalk, Erlang, Ruby, Flash®, Visual Basic®, Lua, and Python®.

Further, at least one example embodiment relates to the non-transitory computer-readable storage medium including electronically readable control information (processor executable instructions) stored thereon, configured in such that when the storage medium is used in a controller of a device, at least one embodiment of the method may be carried out.

The computer readable medium or storage medium may be a built-in medium installed inside a computer device main body or a removable medium arranged so that it can be separated from the computer device main body. The term computer-readable medium, as used herein, does not encompass transitory electrical or electromagnetic signals propagating through a medium (such as on a carrier wave); the term computer-readable medium is therefore considered tangible and non-transitory. Non-limiting examples of the non-transitory computer-readable medium include, but are not limited to, rewriteable non-volatile memory devices (including, for example flash memory devices, erasable programmable read-only memory devices, or a mask read-only memory devices); volatile memory devices (including, for example static random access memory devices or a dynamic random access memory devices); magnetic storage media (including, for example an analog or digital magnetic tape or a hard disk drive); and optical storage media (including, for example a CD, a DVD, or a Blu-ray Disc). Examples of the media with a built-in rewriteable non-volatile memory, include but are not limited to memory cards; and media with a built-in ROM, including but not limited to ROM cassettes; etc. Furthermore, various information regarding stored images, for example, property information, may be stored in any other form, or it may be provided in other ways.

The term code, as used above, may include software, firmware, and/or microcode, and may refer to programs, routines, functions, classes, data structures, and/or objects. Shared processor hardware encompasses a single microprocessor that executes some or all code from multiple modules. Group processor hardware encompasses a microprocessor that, in combination with additional microprocessors, executes some or all code from one or more modules. References to multiple microprocessors encompass multiple microprocessors on discrete dies, multiple microprocessors on a single die, multiple cores of a single microprocessor, multiple threads of a single microprocessor, or a combination of the above.

Shared memory hardware encompasses a single memory device that stores some or all code from multiple modules. Group memory hardware encompasses a memory device that, in combination with other memory devices, stores some or all code from one or more modules.

The term memory hardware is a subset of the term computer-readable medium. The term computer-readable medium, as used herein, does not encompass transitory electrical or electromagnetic signals propagating through a medium (such as on a carrier wave); the term computer-readable medium is therefore considered tangible and non-transitory. Non-limiting examples of the non-transitory computer-readable medium include, but are not limited to, rewriteable non-volatile memory devices (including, for example flash memory devices, erasable programmable read-only memory devices, or a mask read-only memory devices); volatile memory devices (including, for example static random access memory devices or a dynamic random access memory devices); magnetic storage media (including, for example an analog or digital magnetic tape or a hard disk drive); and optical storage media (including, for example a CD, a DVD, or a Blu-ray Disc). Examples of the media with a built-in rewriteable non-volatile memory, include but are not limited to memory cards; and media with a built-in ROM, including but not limited to ROM cassettes; etc. Furthermore, various information regarding stored images, for example, property information, may be stored in any other form, or it may be provided in other ways.

The apparatuses and methods described in this application may be partially or fully implemented by a special purpose computer created by configuring a general purpose computer to execute one or more particular functions embodied in computer programs. The functional blocks and flowchart elements described above serve as software specifications, which can be translated into the computer programs by the routine work of a skilled technician or programmer.

Although described with reference to specific examples and drawings, modifications, additions and substitutions of example embodiments may be variously made according to the description by those of ordinary skill in the art. For example, the described techniques may be performed in an order different with that of the methods described, and/or components such as the described system, architecture, devices, circuit, and the like, may be connected or combined to be different from the above-described methods, or results may be appropriately achieved by other components or equivalents.

Although the present invention has been shown and described with respect to certain example embodiments, equivalents and modifications will occur to others skilled in the art upon the reading and understanding of the specification. The present invention includes all such equivalents and modifications and is limited only by the scope of the appended claims.

What is claimed is:

1. A method for making a recess for a through contact in a semiconductor component, wherein said semiconductor component includes a semiconductor substrate having a rear side and a front side, a first electrical insulation layer on the front side of the semiconductor substrate, a second electrical insulation layer on the first electrical insulation layer, and a contact surface for the semiconductor substrate in or on the second electrical insulation layer, wherein the method comprises:
creating a blind hole-like recess through the semiconductor substrate as far as the first electrical insulation layer;
removing the first electrical insulation layer within the blind hole-like recess;
expanding the blind hole-like recess in a direction towards the contact surface by partially removing the second electrical insulation layer;
applying a third electrical insulation layer to inner walls of the expanded recess, wherein the first electrical insulation layer is covered up to the expanded recess; and
anisotropic etching the second electrical insulation layer in the direction towards the contact surface until the contact surface for the semiconductor substrate is revealed.

2. The method as claimed in claim 1, wherein the semiconductor component further includes a test contact in contact with the contact surface.

3. The method as claimed in claim 2, wherein the test contact overlaps with a planar extent of the contact surface.

4. The method as claimed in claim 2, wherein the test contact has a material thickness greater than a thickness of a contact surface material.

5. The method as claimed in claim 3, wherein the test contact has a material thickness greater than a thickness of a contact surface material.

6. The method as claimed in claim 1, wherein
the first electrical insulation layer comprises silicon nitride, and
the second electrical insulation layer and the third electrical insulation layer comprise silicon dioxide.

7. The method as claimed in claim 1, wherein the creating a blind hole-like recess comprises etching.

8. The method as claimed in claim 1, wherein the partially removing the second electrical insulation layer comprises etching the second electrical insulation layer.

9. A method for making a through contact in a semiconductor component, the method comprising:
carrying out the method as claimed in claim 1;
applying a barrier layer to a surface of the third electrical insulation layer facing away from the first electrical insulation layer and to the contact surface in the recess;
applying a conductor track to the semiconductor substrate and to the barrier layer in the recess;
applying a first rear-side passivization layer to the conductor track; and
applying a contact element to the conductor track.

10. The method as claimed in claim 9, wherein the conductor track includes:
copper,
aluminum, or
tungsten.

11. The method as claimed in claim 9, wherein at least one of
the first rear-side passivization layer includes nickel, silicon dioxide, or platinum, or
the contact element includes gold.

12. The method as claimed in claim 9, wherein the rear side of the semiconductor substrate is structured and provided with a second rear-side passivization layer on the third electrical insulation layer and on the conductor track.

13. The method as claimed in claim 12, wherein the second rear-side passivization layer includes:
polyimide,
silicon nitride, or
silicon dioxide.

14. A semiconductor component comprising:
a semiconductor substrate having a rear side and a front side;
a first electrical insulation layer on the front side of the semiconductor substrate;
a second electrical insulation layer on the first electrical insulation layer;
a contact surface for the semiconductor substrate in or on the second electrical insulation layer; and
a recess for a through contact between the semiconductor substrate and the contact surface, wherein
the recess reaches the contact surface and a third electrical insulation layer is on inner walls of the recess, and
the first electrical insulation layer is covered up to the recess by the third electrical insulation layer.

15. The semiconductor component as claimed in claim 14, further comprising:
a barrier layer on a surface of the third electrical insulation layer facing away from the first electrical insulation layer and on the contact surface in the recess,
a conductor track on the semiconductor substrate and on the barrier layer in the recess,
a first rear-side passivization layer on the conductor track, and
a contact element on the first rear-side passivization layer.

16. The semiconductor component as claimed in claim 15, further comprising:
a structured rear side of the semiconductor substrate, and
a second rear-side passivization layer on the third electrical insulation layer and on the conductor track.

17. The semiconductor component as claimed in claim 14, further comprising:
a test contact in contact with the contact surface.

18. The semiconductor component as claimed in claim 17,
wherein the test contact overlaps with a planar extent of the contact surface.

19. The semiconductor component as claimed in claim 17,
wherein the test contact has a material thickness greater than a thickness of a contact surface material.

20. An x-ray detector module, comprising:
a sensor unit;
a semiconductor component as claimed in claim 14, wherein the semiconductor substrate of the semiconductor component includes counting electronics, which are electrically connected to the semiconductor component;
a distribution unit electrically connected to the semiconductor component; and
an evaluation unit electrically connected to the distribution unit.
